(19) United States
(12) Patent Application Publication
(10) Pub. No.: US 2025/0138302 A1
(43) Pub. Date: May 1, 2025

(54) OPTICAL ASSEMBLY, PROJECTION EXPOSURE SYSTEM FOR SEMICONDUCTOR LITHOGRAPHY, AND METHOD

(71) Applicant: Carl Zeiss SMT GmbH, Oberkochen (DE)

(72) Inventor: Thilo Pollak, Neresheim (DE)

(21) Appl. No.: 19/004,166

(22) Filed: Dec. 27, 2024

Related U.S. Application Data
(63) Continuation of application No. PCT/EP2023/062473, filed on May 10, 2023.

(30) Foreign Application Priority Data
Jul. 5, 2022 (DE) 10 2022 116 700.3

(51) Int. Cl. G02B 26/08; G03F 7/00

(52) U.S. Cl. CPC G02B 26/0825; G03F 7/70266; G03F 7/70316; G03F 7/7085

(57) ABSTRACT

An optical assembly has an optical element which comprises a main body. At least one actuator serves to deform the main body and is arranged on the back side of the main body. The at least one actuator is connected at a first connecting surface to the back side of the main body. The at least one actuator is connected at a second connecting surface to a back plate. The back plate is mounted exclusively by way of the actuator.

### CROSS-REFERENCE TO RELATED APPLICATIONS

The present application is a continuation of, and claims benefit under 35 USC 120 to, international application No. PCT/EP2023/062473, filed May 10, 2023, which claims benefit under 35 USC 119 of German Application No. 10 2022 116 700.3, filed Jul. 5, 2022. The entire disclosure of each of these applications is incorporated by reference herein.

### FIELD

The disclosure relates to an optical assembly, a projection exposure apparatus for semiconductor lithography and a method for producing an optical assembly.

### BACKGROUND

In projection exposure apparatuses for semiconductor lithography, photolithographic methods starting with a mask as a template are used to image microscopically small structures in much reduced fashion on a photoresist-coated wafer. In subsequent development and further processing steps, the desired structures such as memory or logic elements are created on the wafer, which is subsequently divided into individual chips for use in electronic equipment.

On account of the extremely small structures to be created, which go down into the nanometer range, relatively extreme desired properties for the optical units of the projection exposure apparatuses and hence on the optical elements used. Moreover, aberrations frequently caused by fluctuating ambient conditions such as temperature fluctuations in the optical unit regularly occur during the operation of a corresponding apparatus. Typically, this is addressed by virtue of the used optical elements, such as lens elements or mirrors, having a movable or else deformable embodiment in order to be able to correct the aforementioned aberrations during the operation of the apparatus. To this end, use is generally made of mechanical actuators which for example can be suitable for deforming the surface of an optical element used for imaging purposes, i.e. the so-called optically effective surface, in a targeted manner. This deformation can be implemented from the back side of a main body of the corresponding optical element. According to the prior art, the mechanical action of the actuators is typically rendered possible by virtue of the actuators being mechanically supported on a back plate in the rearward region of the main body. This back plate, for example the mounting thereof, in turn causes parasitic deformations when actuating the optical element. The desired properties for manufacturing and assembly tolerances of the actuators and back plate derived therefrom can, in general, only be met with very much outlay.

### SUMMARY

The present disclosure seeks to provide an optical assembly and a projection exposure apparatus in which disadvantageous effects caused by back plates connected to actuators can be reduced in comparison with certain known systems. The present disclosure also seeks to provide a method for producing such an assembly.

In an aspect, the disclosure provides an optical assembly comprising an optical element, wherein the optical element comprises a main body and wherein at least two actuators serving to deform the main body is arranged on the back side of the main body. In this case, the at least two actuators are connected at a first connecting surface to the back side of the main body and connected at a second connecting surface to a back plate, wherein the back plate is mounted exclusively by way of the actuators.

In other words, the only connection between the back plate and the “stationary surroundings” consists in the at least two actuators or typically a plurality of actuators. The actuators can be solid-state actuators such as piezo actuators, or magnetostrictive, electrostrictive or thermal actuators. A homogeneous, e.g. thermally induced expansion of all solid-state actuators perpendicular to a connecting surface thus can lead only to a displacement of the back plate and has no effect on the shape and pose of the optically effective surface. Actuator creepage, as it is known, often occurs during switch-on procedures in particular, i.e. the actuators are not immediately stable following the switch-on but move toward the desired state. However, since the actuators typically behave similarly in the process, this effect is largely compensated by the free back plate, or no unwanted deformation is created.

Moreover, even a constant temperature gradient over the optical assembly would only lead to a tilt of the back plate, and not to a displacement or deformation of the optically effective surface.

In addition to the faults arising from homogeneous changes in all actuators, systems according to the disclosure also allow suppression of parasitic effects from the joining technology. Inter alia, this includes thermally induced or moisture-induced changes in volume of a joining substance in a vertical direction with respect to the connecting surfaces. In this context, a joining substance is understood to mean any substance which establishes the joint of actuator and adjoining component part (main body and back plate in this case). Examples to this end are adhesives, glass frits, solders, welding fillers, reactive layers made by reactive bonding, etc.

Since many actuators give rise not only to the desired lengthening in the actuation direction but also to a change in the actuator geometry in the transverse direction that may lead to parasitic deformations, at least one decoupling element for lateral decoupling purposes can be arranged between the actuator and at least the main body and/or the back plate in a particularly preferred embodiment.

This lateral decoupling can also make it possible to compensate for thermal expansions of the joining substance in the transverse direction and moisture-induced geometry changes in these directions; a similar statement can apply to pressure-induced volume changes.

In a variant of the disclosure, the back side of the main body has at least one flat portion. The flat joining points created thereby can allow the use of simple manufacturing methods with good roughness and very good shape tolerance or planarity. Specific mention should be made here of grinding, lapping, flat honing and flat polishing. Thus, it is possible to use joining methods that enable only the compensation of small mechanical tolerances. For examples, these include the aforementioned joining methods.

The main body can have a thickness that varies over its lateral extent. For example, installation space considerations might make it desirable to manufacture the main body so as to be locally thinner. In this case, it might be desirable to adapt the respective actuators and/or also the embodiment of the back plate accordingly.

The back plate can likewise have a thickness that varies over its lateral extent. For example, when compared to the inner regions, the back plate might have an increased thickness in its regions close to the edge in order to compensate for the loss of stiffness in the back plate caused by the proximity to the edge.

To save installation space, it might also be expedient for the back plate and/or the main body to have cutouts, in which actuators are arranged at least in part.

Especially in the case of strongly curved mirrors as optical elements, it might be desirable for the back side of the main body to have a plurality of flat portions that do not extend parallel to one another. What this can achieve is a limited variation of the overall thickness of the main body, and so its mechanical properties over the extent thereof also vary within a controllable range.

Especially in this case it can be desirable for a plurality of flat back plates to be present, each of which can be aligned in parallel with the flat portions.

In an embodiment of the disclosure, the surface of the back plate facing the main body and the surface of the back plate facing away from the main body extend in each case at a constant distance from the back side of the main body. For example, this can create a back plate of constant thickness. This variant is also conceivable for cases in which the optical element is embodied as a spherical mirror with a main body of constant thickness. In this case, the back plate would be substantially a similar mapping of the main body.

As an example, the present disclosure encompasses cases in which the effective direction of at least one of the actuators is developed normally to the connecting surface of the actuator with the main body. However, it is also applicable to situations in which the effective direction of at least one of the actuators is developed normally to the optically effective surface.

Especially in cases in which the main body is not formed with uniform thickness, it might be desirable for at least two actuators to be formed with different properties. As a result, it is possible to take account of the mechanical properties of the main body, such as stiffness, which differ laterally. This can allow the utilized actuators to be adapted to the mechanical conditions of the main body at the respective position, for example with regard to their inherent stiffness, their travel or else the maximum force that they can apply.

As mentioned, the optical element can be a mirror, such as a multilayer mirror. Likewise, the mirror can be a concave mirror with a radius of curvature of 180 mm-260 mm, such as of the order of 220 mm. Such mirrors are used for folding the beam path, especially in DUV projection exposure apparatuses.

In a variant of the disclosure, the back plate has a lower stiffness than the main body and can be provided with at least one sensor, for example. The sensor can be a strain or temperature sensor.

It is also conceivable that both the back plate and the main body are equipped with additional sensor systems or else with temperature-control elements such as cooling channels.

What can be achieved as a result of the back plate being able to have a lower stiffness than the main body—as mentioned—is that in the event of controlling the actuator system in order to obtain a desired deformation of the optically effective surface, a greater deformation of the back plate is set in comparison with the deformation of the effective surface. This increased deformation has a positive effect, for example, on the signal-to-noise ratio of a strain measurement of the back plate, for example using fiber Bragg grating sensors. In the event of known mechanical properties of actuators, main body and back plate, a corresponding deformation of the optically effective surface can then be deduced, on the basis of models, from a local deformation of the back plate.

In an embodiment, the properties (coefficient of thermal expansion and thickness of the actuators used) can be chosen such that a defined temperature profile (e.g. the thermal main mode of the system) does not lead to a parasitic deformation or displacement of the optically effective surface. For example, such a parasitic deformation can be due to the fact that heating of the actuators influences their efficiency, i.e. their respective mechanical response to a change in control voltage. Furthermore, there is the possibility that parasitic deformations are caused purely on account of the usual thermal expansion or contraction of the materials involved. A suitable choice of the material used and/or of the design of the respective geometry can provide the possibility of achieving at least partial mutual compensation of the aforementioned effects.

As already mentioned, the disclosure is suitable for use in a projection exposure apparatus for semiconductor lithography.

A method according to the disclosure for producing a corresponding optical assembly comprises the following method steps:
connecting the actuator to the back plate,
   determining the surface-area tolerance of the connecting surface of the actuator facing away from the back plate,
   processing the connecting surfaces,
   repeating the two previous steps until the surface-area tolerance is below a predetermined threshold value,
   connecting the actuator to the main body.

In the process, the optically effective surface can be processed following the assembly of the actuator. The method can be implemented particularly advantageously should a plurality of actuators be arranged on the back plate, the connecting surfaces of which can be processed together.

### BRIEF DESCRIPTION OF THE DRAWINGS

Exemplary embodiments and variants of the disclosure are explained in detail below on the basis of the drawings, in which:

FIG. 1 schematically shows a meridional plane section of a projection exposure apparatus for EUV projection lithography,

FIG. 2 schematically shows a meridional plane section of a projection exposure apparatus for DUV projection lithography,

FIG. 3 shows a schematic illustration of a first embodiment of the disclosure,

FIG. 4 shows a further embodiment of the disclosure,

FIG. 5 shows a further embodiment of the disclosure,

FIG. 6 shows a further embodiment of the disclosure,

FIGS. 7A-7B show a further embodiment of the disclosure,

FIGS. 8A-8C show a detailed illustration of further embodiments of the disclosure,

FIG. 9 shows a schematic illustration regarding possible decoupling elements,

FIG. 10 shows a variant for designing the back plate, and

FIG. 11 shows a flowchart for a production method according to the disclosure.

### DETAILED DESCRIPTION

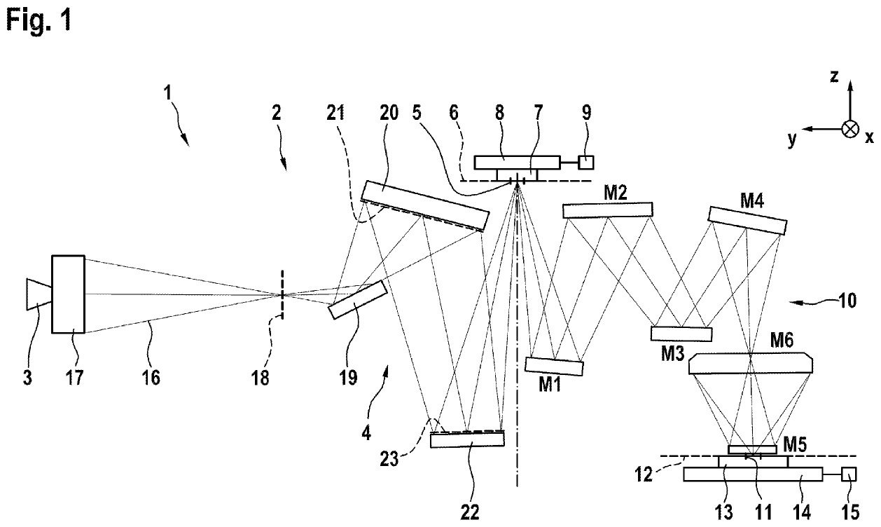

Certain constituent parts of a microlithographic projection exposure apparatus 1 are initially described by way of example below with reference to FIG. 1. The description of the basic construction of the projection exposure apparatus 1 and its constituent parts should not be construed as restrictive here.

One embodiment of an illumination system 2 of the projection exposure apparatus 1 has, in addition to a radiation source 3, an illumination optical unit 4 for illuminating an object field 5 in an object plane 6. In an alternative embodiment, the light source 3 can also be provided as a module separate from the rest of the illumination system. In this case, the illumination system does not comprise the light source 3.

A reticle 7 arranged in the object field 5 is illuminated. The reticle 7 is held by a reticle holder 8. The reticle holder 8 is displaceable by way of a reticle displacement drive 9, in particular in a scanning direction.

For explanation purposes, a Cartesian xyz-coordinate system is depicted in FIG. 1. The x-direction runs perpendicularly to the plane of the drawing into the latter. The y-direction runs horizontally, and the z-direction runs vertically. The scanning direction runs in the y-direction in FIG. 1. The z-direction runs perpendicularly to the object plane 6.

The projection exposure apparatus 1 comprises a projection optical unit 10. The projection optical unit 10 serves for imaging the object field 5 into an image field 11 in an image plane 12. The image plane 12 extends parallel to the object plane 6. Alternatively, an angle that differs from 0° between the object plane 6 and the image plane 12 is also possible.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15, in particular in the y-direction. The displacement, firstly, of the reticle 7 by way of the reticle displacement drive 9 and, secondly, of the wafer 13 by way of the wafer displacement drive 15 can be implemented so as to be synchronized with one another.

The radiation source 3 is an EUV radiation source. The radiation source 3 emits, in particular, EUV radiation 16, which is also referred to below as used radiation, illumination radiation or illumination light. In particular, the used radiation has a wavelength in the range of between 5 nm and 30 nm. The radiation source 3 can be a plasma source, for example an LPP (Laser Produced Plasma) source or a GDPP (Gas Discharge Produced Plasma) source. It can also be a synchrotron-based radiation source. The radiation source 3 can be a free electron laser (FEL).

The illumination radiation 16 emanating from the radiation source 3 is focused by a collector 17. The collector 17 can be a collector with one or more ellipsoidal and/or hyperboloidal reflection surfaces. The illumination radiation 16 can be incident on the at least one reflection surface of the collector 17 with grazing incidence (GI), i.e. at angles of incidence of greater than 45° with respect to the normal direction of the mirror surface, or with normal incidence (NI), i.e. at angles of incidence of less than 45°. The collector 17 can be structured and/or coated firstly to optimize its reflectivity for the used radiation and secondly to suppress extraneous light.

Downstream of the collector 17, the illumination radiation 16 propagates through an intermediate focus in an intermediate focal plane 18. The intermediate focal plane 18 can constitute a separation between a radiation source module, comprising the radiation source 3 and the collector 17, and the illumination optical unit 4.

The illumination optical unit 4 comprises a deflection mirror 19 and, disposed downstream thereof in the beam path, a first facet mirror 20. The deflection mirror 19 can be a plane deflection mirror or, alternatively, a mirror with a beam-influencing effect that goes beyond the purely deflecting effect. In an alternative to that or in addition, the deflection mirror 19 can be embodied as a spectral filter separating a used light wavelength of the illumination radiation 16 from extraneous light at a wavelength that deviates therefrom. If the first facet mirror 20 is arranged in a plane of the illumination optical unit 4 that is optically conjugate to the object plane 6 as a field plane, the facet mirror is also referred to as a field facet mirror. The first facet mirror 20 comprises a multiplicity of individual first facets 21, which are also referred to below as field facets. FIG. 1 illustrates only some of the facets 21 by way of example.

The first facets 21 can be embodied as macroscopic facets, in particular as rectangular facets or as facets with an arcuate edge contour or an edge contour of part of a circle. The first facets 21 can be embodied as plane facets or alternatively as convexly or concavely curved facets.

As known for example from DE 10 2008 009 600 A1, the first facets 21 themselves can also be composed in each case of a multiplicity of individual mirrors, in particular a multiplicity of micromirrors. The first facet mirror 20 can be designed in particular as a microelectromechanical system (MEMS system). For details, reference is made to DE 10 2008 009 600 A1.

Between the collector 17 and the deflection mirror 19, the illumination radiation 16 runs horizontally, i.e. in the y-direction.

In the beam path of the illumination optical unit 4, a second facet mirror 22 is disposed downstream of the first facet mirror 20. If the second facet mirror 22 is arranged in a pupil plane of the illumination optical unit 4, it is also referred to as a pupil facet mirror. The second facet mirror 22 can also be arranged at a distance from a pupil plane of the illumination optical unit 4. In this case, the combination of the first facet mirror 20 and the second facet mirror 22 is also referred to as a specular reflector. Specular reflectors are known from US 2006/0132747 A1, EP 1 614 008 B1 and U.S. Pat. No. 6,573,978.

The second facet mirror 22 comprises a plurality of second facets 23. In the case of a pupil facet mirror, the second facets 23 are also referred to as pupil facets.

The second facets 23 can likewise be macroscopic facets, which can, for example, have a round, rectangular or else hexagonal edge, or alternatively be facets composed of micromirrors. In this regard, reference is likewise made to DE 10 2008 009 600 A1.

The second facets 23 can have plane reflection surfaces or, alternatively, convexly or concavely curved reflection surfaces.

The illumination optical unit 4 consequently forms a doubly faceted system. This fundamental principle is also referred to as a fly's eye condenser (fly's eye integrator).

It can be advantageous to arrange the second facet mirror 22 not exactly in a plane that is optically conjugate to a pupil plane of the projection optical unit 10. In particular, the pupil facet mirror 22 can be arranged so as to be tilted relative to a pupil plane of the projection optical unit 10, as is described, for example, in DE 10 2017 220 586 A1.

With the aid of the second facet mirror 22, the individual first facets 21 are imaged into the object field 5. The second facet mirror 22 is the last beam-shaping mirror or else actually the last mirror for the illumination radiation 16 in the beam path upstream of the object field 5.

In a further embodiment (not illustrated) of the illumination optical unit 4, a transfer optical unit contributing in particular to the imaging of the first facets 21 into the object field 5 can be arranged in the beam path between the second facet mirror 22 and the object field 5. The transfer optical unit can have exactly one mirror or, alternatively, two or more mirrors, which are arranged in succession in the beam path of the illumination optical unit 4. The transfer optical unit can in particular comprise one or two normal-incidence mirrors (NI mirrors) and/or one or two grazing-incidence mirrors (GI mirrors).

In the embodiment shown in FIG. 1, the illumination optical unit 4 has exactly three mirrors downstream of the collector 17, specifically the deflection mirror 19, the field facet mirror 20, and the pupil facet mirror 22.

In a further embodiment of the illumination optical unit 4, the deflection mirror 19 can also be omitted, and so the illumination optical unit 4 can then have exactly two mirrors downstream of the collector 17, specifically the first facet mirror 20 and the second facet mirror 22.

The imaging of the first facets 21 into the object plane 6 via the second facets 23 or using the second facets 23 and a transfer optical unit is routinely only approximate imaging.

The projection optical unit 10 comprises a plurality of mirrors Mi, which are consecutively numbered in accordance with their arrangement in the beam path of the projection exposure apparatus 1.

In the example illustrated in FIG. 1, the projection optical unit 10 comprises six mirrors M1 to M6. Alternatives with four, eight, ten, twelve or any other number of mirrors Mi are likewise possible. The penultimate mirror M5 and the last mirror M6 each have a passage opening for the illumination radiation 16. The projection optical unit 10 is a doubly obscured optical unit. The projection optical unit 10 has an image-side numerical aperture that is greater than 0.5 and can also be greater than 0.6 and can be for example 0.7 or 0.75.

Reflection surfaces of the mirrors Mi can be embodied as freeform surfaces without an axis of rotational symmetry. Alternatively, the reflection surfaces of the mirrors Mi can be designed as aspherical surfaces with exactly one axis of rotational symmetry of the reflection surface shape. Just like the mirrors of the illumination optical unit 4, the mirrors Mi can have highly reflective coatings for the illumination radiation 16. These coatings can be designed as multilayer coatings, in particular with alternating layers of molybdenum and silicon.

The projection optical unit 10 has a large object-image offset in the y-direction between a y-coordinate of a center of the object field 5 and a y-coordinate of the center of the image field 11. This object-image offset in the y-direction can be of approximately the same magnitude as a z-distance between the object plane 6 and the image plane 12.

In particular, the projection optical unit 10 can have an anamorphic design. In particular, it has different imaging scales βₓ, β_{y} in the x- and y-directions. The two imaging scales βₓ, β_{y} of the projection optical unit 10 are preferably at (βₓ, β_{y})=(+/−0.25, +/−0.125). A positive imaging scale β means imaging without an image inversion. A negative sign for the imaging scale β means imaging with an image inversion.

The projection optical unit 10 consequently leads to a reduction in size with a ratio of 4:1 in the x-direction, i.e. in a direction perpendicular to the scanning direction.

The projection optical unit 10 leads to a reduction in size of 8:1 in the y-direction, i.e. in the scanning direction.

Other imaging scales are likewise possible. Imaging scales with the same signs and the same absolute values in the x-direction and y-direction, for example with absolute values of 0.125 or 0.25, are also possible.

The number of intermediate image planes in the x-direction and in the y-direction in the beam path between the object field 5 and the image field 11 can be the same or can differ depending on the embodiment of the projection optical unit 10. Examples of projection optical units with different numbers of such intermediate images in the x- and y-directions are known from US 2018/0074303 A1.

In each case one of the pupil facets 23 is assigned to exactly one of the field facets 21 for the purpose of forming a respective illumination channel for illuminating the object field 5. This can in particular result in illumination according to the Köhler principle. The far field is decomposed into a multiplicity of object fields 5 with the aid of the field facets 21. The field facets 21 create a plurality of images of the intermediate focus on the pupil facets 23 respectively assigned thereto.

The field facets 21 are each imaged by an assigned pupil facet 23 onto the reticle 7 in a manner overlaid on one another in order to illuminate the object field 5. The illumination of the object field 5 is in particular as homogeneous as possible. It preferably has a uniformity error of less than 2%. Field uniformity can be attained by overlaying different illumination channels.

The illumination of the entrance pupil of the projection optical unit 10 can be defined geometrically by way of an arrangement of the pupil facets. The intensity distribution in the entrance pupil of the projection optical unit 10 can be set by selecting the illumination channels, in particular the subset of the pupil facets which guide light. This intensity distribution is also referred to as illumination setting.

A likewise preferred pupil uniformity in the region of portions of an illumination pupil of the illumination optical unit 4 which are illuminated in a defined manner can be achieved by a redistribution of the illumination channels.

Further aspects and details of the illumination of the object field 5 and in particular of the entrance pupil of the projection optical unit 10 are described hereinafter.

The projection optical unit 10 can have a homocentric entrance pupil, in particular. The latter can be accessible. It can also be inaccessible.

The entrance pupil of the projection optical unit 10 regularly cannot be exactly illuminated using the pupil facet mirror 22. In the case of imaging of the projection optical unit 10 which telecentrically images the center of the pupil facet mirror 22 onto the wafer 13, the aperture rays often do not intersect at a single point. However, it is possible to find an area in which the pairwise determined spacing of the aperture rays becomes minimal. This area represents the entrance pupil or an area in real space conjugate thereto. In particular, this area exhibits a finite curvature.

It may be the case that the projection optical unit 10 has different positions of the entrance pupil for the tangential beam path and for the sagittal beam path. In this case, an imaging element, in particular an optical component of the transfer optical unit, should be provided between the second facet mirror 22 and the reticle 7. With the aid of this optical element, the different position of the tangential entrance pupil and the sagittal entrance pupil can be taken into account.

In the arrangement of the components of the illumination optical unit 4 illustrated in FIG. 1, the pupil facet mirror 22 is arranged in an area conjugate to the entrance pupil of the projection optical unit 10. The field facet mirror 20 is arranged so as to be tilted with respect to the object plane 6. The first facet mirror 20 is arranged so as to be tilted with respect to an arrangement plane defined by the deflection mirror 19.

The first facet mirror 20 is arranged so as to be tilted with respect to an arrangement plane defined by the second facet mirror 22.

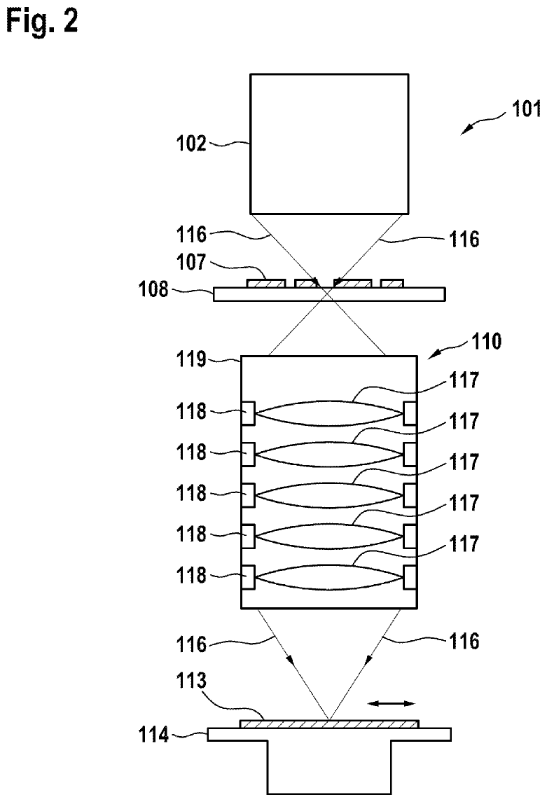

FIG. 2 schematically shows a meridional plane section of a further projection exposure apparatus 101 for DUV projection lithography, in which the disclosure can likewise find use.

The construction of the projection exposure apparatus 101 and the imaging principle are comparable to the construction and procedure described in FIG. 1. The same components have been denoted by a reference sign with a numerical value that has been increased by 100 vis-à-vis FIG. 1; thus, the reference signs in FIG. 2 start at 101.

In contrast with an EUV projection exposure apparatus 1 as described in FIG. 1, refractive, diffractive and/or reflective optical elements 117, such as lens elements, mirrors, prisms, terminating plates, and the like, can be used for imaging or for illumination in the DUV projection exposure apparatus 101 on account of the longer wavelength of the DUV radiation 116, employed as used light, in the range from 100 nm to 300 nm, in particular of the order of 193 nm. The projection exposure apparatus 101 in this case substantially comprises an illumination system 102, a reticle holder 108 for receiving and exactly positioning a reticle 107 provided with a structure, the reticle determining the later structures on a wafer 113, a wafer holder 114 for holding, moving and exactly positioning that same wafer 113, and a projection lens 110, with a plurality of optical elements 117, which are held by way of mounts 118 in a lens housing 119 of the projection lens 110.

The illumination system 102 provides DUV radiation 116 used for the imaging of the reticle 107 on the wafer 113. A laser, a plasma source or the like can be used as the source of this radiation 116. The radiation 116 is shaped in the illumination system 102 via optical elements such that the DUV radiation 116 has the desired properties with regard to diameter, polarization, shape of the wavefront and the like when it is incident on the reticle 107.

Apart from the additional use of refractive optical elements 117, such as lens elements, prisms, terminating plates, the structure of the downstream projection optical unit 110 with the lens housing 119 fundamentally does not differ from the structure described in FIG. 1 and is therefore not described in more detail.

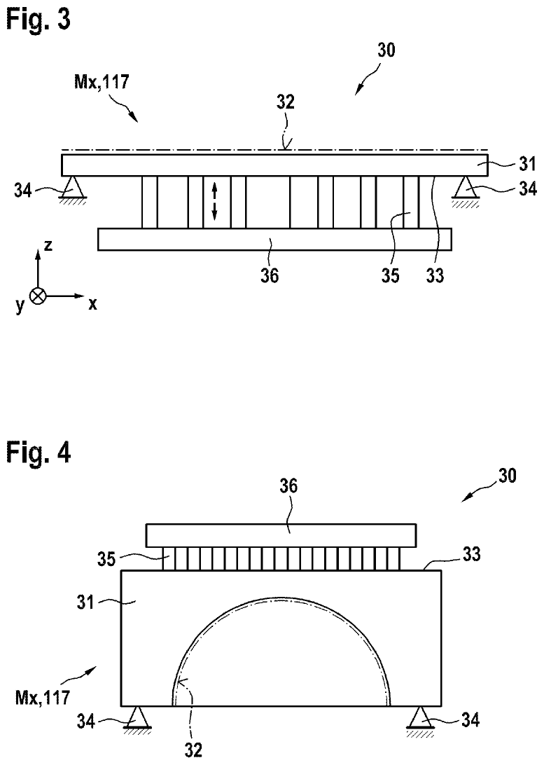

In a schematic illustration, FIG. 3 shows a first embodiment of the disclosure, in which an optical assembly 30 is depicted. The latter comprises an optical element designed as a mirror Mx, 117 and as able to find use in one of the projection exposure apparatuses 1, 101 explained in FIG. 1 and in FIG. 2, actuators 35 and a support structure designed as a back plate 36. The mirror Mx, 117 comprises a main body 31 with an optically effective surface 32, wherein the main body 31 is mounted on a bearing 34, for example a frame of a projection exposure apparatus 1, 101. The actuators 35 are arranged between the main body 31 and the back plate 36 and connected to the main body 31 on the back side 33 of the main body 31 opposite the optically effective surface 32. The actuators 35 can be connected to the main body 31 and the back plate 36 by way of an adhesive connection not depicted separately in the figure, with other types of connection, for example bonding or soldering, also being able to be applied.

By way of a controller (likewise not depicted in the figure), the actuators 35 are controlled in such a way that the deflection of the actuators 35 brings about a deformation of the optically effective surface 32. The back plate 36 is deformed as a result of the different extents of deflection of the actuators 35, and so a deformation of the main body 31, which depends on the ratio of stiffness of the main body 31 to stiffness of the back plate 36, and hence a deformation of the optically effective surface 32, is set. Thus, some of the actuators 35 hold the back plate secure in its position, whereby another portion of the actuators 35 can be supported on the back plate 36 and thereby bring about deformation. In this case, the back plate 36 is mounted exclusively by the actuators 35 and thus not connected to a frame or to the main body 31 of the mirror Mx, 117 or to any other component. This is advantageous in that a homogeneous effect that acts on all actuators 35 in the same way, a temperature increase or a drift in the control of the actuators 35 for example, has no effect on the optically effective surface 32 and only leads to a displacement of the free back plate 36. In the figure, three strain sensors 49 serving to measure the deformation of the back plate 37.3 are depicted by way of example on the back plate 37.3.

FIG. 4 shows a further embodiment of the disclosure, in which an optical assembly 30 having an optical element designed as a mirror Mx, 117 and as able to find use in one of the projection exposure apparatuses 1, 101 explained in FIG. 1 and in FIG. 2 is depicted. The mirror Mx, 117 comprises a main body 31 with a concavely formed optically effective surface 32. The optical assembly 30 also comprises a back plate 36 and actuators 35 that are arranged between the back plate 36 and the back side 33 of the main body 31. The back side 33 and the back plate 36 have a flat embodiment. This is advantageous in that the actuators 35 are also arranged in a plane and following the initial connection to the back plate 36 can be post-processed in order to achieve an optimal adaptation to the back side 33. As a result, the adhesive gap of the adhesive connection between the actuators 35 and the main body 31 can be configured in such a way that the influence of the adhesive on the connection stiffness is negligible. The material thickness of the main body 31, which varies laterally, can be compensated for by way of differently designed actuators and the control of the actuators 35.

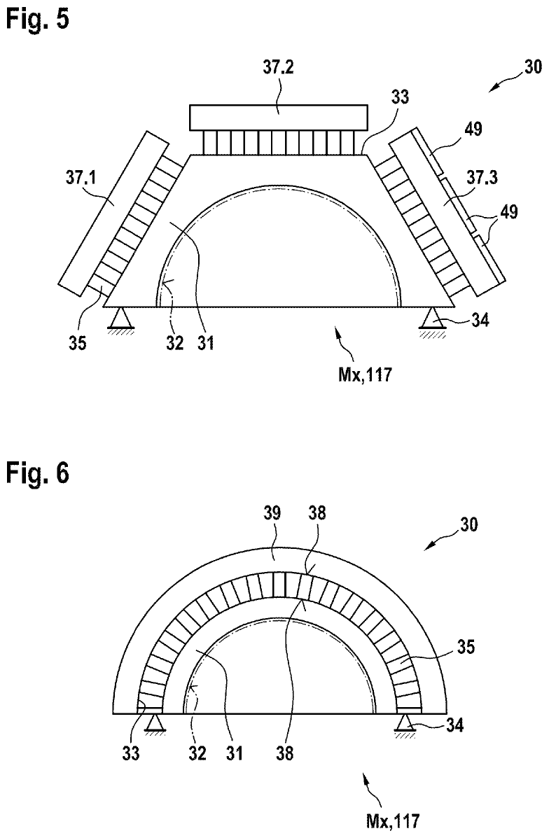

FIG. 5 shows a further embodiment of the disclosure, in which an optical assembly 30 having an optical element designed as a mirror Mx, 117 and as able to find use in one of the projection exposure apparatuses 1, 101 explained in FIG. 1 and in FIG. 2 is depicted. The mirror Mx, 117 comprises a main body 31 with a concavely formed optically effective surface 32. The optical assembly 30 furthermore comprises three back plates 37.1, 37.2, 37.3 and actuators 35 that are arranged between the back plates 37.1, 37.2, 37.3 and the back side 33 of the main body 31. The main body 31 is designed such that the differences in the distance between the back side 33 of the main body 31 in the form of three flat surfaces and the optically effective surface 32 are minimized in comparison with the embodiment explained in FIG. 4. As already explained in FIG. 4, the back plates 37.1, 37.2, 37.3 are flat and can thus be produced easily, and the actuators 20) 35 can be in the form of standard actuators.

FIG. 6 shows a further embodiment of the disclosure, in which an optical assembly 30 having an optical element designed as a mirror Mx, 117 and as able to find use in one of the projection exposure apparatuses 1, 101 explained in FIG. 1 and in FIG. 2 is depicted. The mirror Mx, 117 comprises a main body 31 with a concavely formed optically effective surface 32. Unlike the main body depicted in FIG. 5, the main body 31 in the embodiment shown has a constant thickness, and so this results in a convex or spherical back side 33. The optical assembly 30 furthermore comprises a concavely shaped back plate 39 that corresponds to the optically effective surface 32 and the geometry of the main body 31. The actuators 35 comprise a spherical joining surface 38 on both sides in order to ensure an adhesive gap of constant thickness in the adhesive connection. The back plate 39 and the main body 31 having a constant thickness is advantageous in that the parts have a constant stiffness, whereby all actuators apply a comparable force in order to bring about an identical deformation of the optically effective surface 32. This increases the number of similar parts and thereby reduces the production costs.

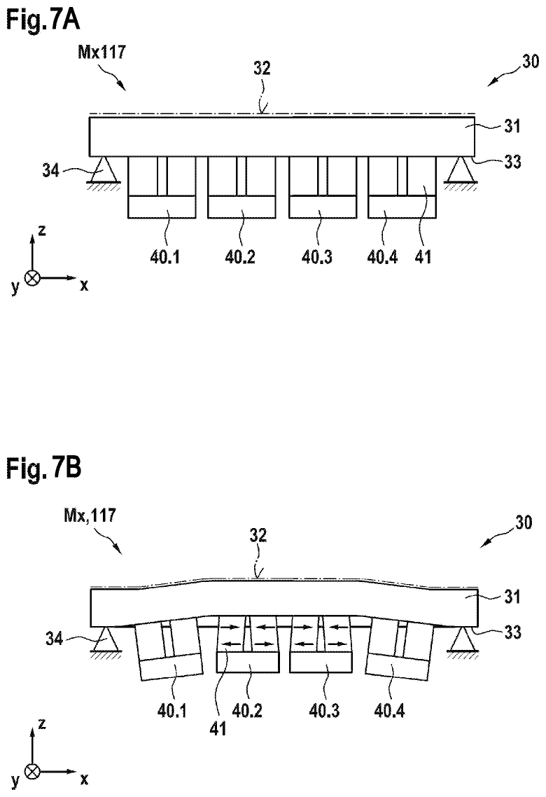

FIGS. 7A and 7B show a further embodiment of the disclosure in two operating states, in which an optical assembly 30 having an optical element designed as a mirror Mx, 117 and as able to find use in one of the projection exposure apparatuses 1, 101 explained in FIG. 1 and in FIG. 2 is depicted. The mirror Mx, 117 comprises a main body 31 with a flat optically effective surface 32. Furthermore, the optical assembly 30 comprises four back plates 40.1, 40.2, 40.3, 40.4. Two respective shearing actuators 41 which perform a shearing movement parallel to the optically effective surface 32 upon application of a voltage are arranged between each back plate 40.1, 40.2, 40.3, 40.4 and the back side 33 of the main body 31.

In this case, FIG. 7A shows a so-called zero state, in which the optically effective surface 32 of the main body 31 has no deformations, i.e. corresponds to its target surface shape. The shearing actuators 41 are deflected from a voltage-free zero position, as a result of which the main body 31 is deformed out of its zero position in one direction, depending on the voltage applied. This is advantageous in that the optically effective surface 32 can be fully processed prior to the assembly of the actuators 41.

FIG. 7B shows the same optical assembly 30 in a deflected operating state. The actuators 41 arranged between the two central back plates 40.2, 40.3 and the main body 31 are deflected and bring about a deformation of the main body 31, and hence a deformation of the optically effective surface 32. Whereas both actuators of a back plate 40.2, 40.3 are deflected relative to one another in FIG. 7B, it might also be the case that only one actuator 41 of a back plate 40.1, 40.2, 40.3, 40.4 is deflected or a respective actuator 41 from two adjacently arranged back plates 40.1, 40.2, 40.3, 40.4 is deflected.

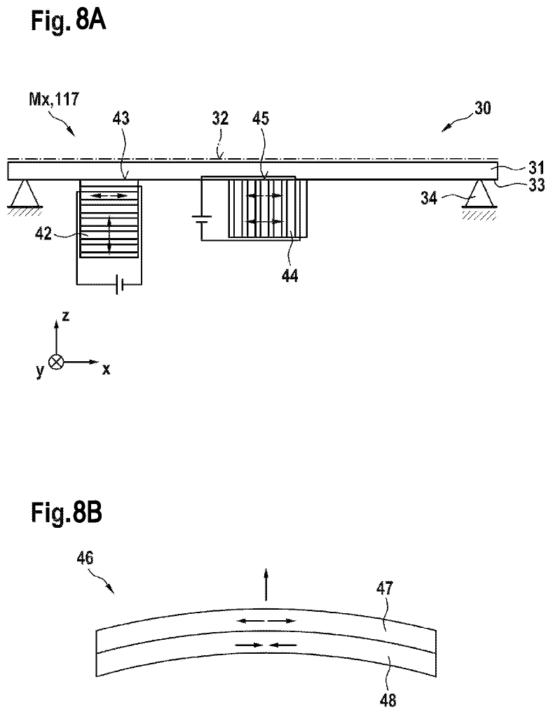

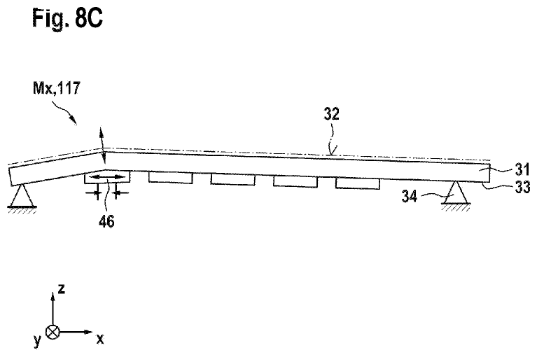

FIGS. 8A, 8B and 8C show different embodiments of actuators 42, 44, 46 which are deflected parallel to the optically effective surface 32.

FIG. 8A shows an optical element embodied as a mirror Mx, 117 with an actuator 42 on the left side whose end face 43 is connected to the back side 33 of the main body 31. The electric field of the actuator 42 is developed perpendicular to the optically effective surface 32, whereas the deflection extends parallel to the optically effective surface 32, as already explained above. By contrast, the actuator 44 on the right side of the mirror Mx is connected by way of its longitudinal side 45 to the main body 31. The actuator 44 is designed as a stack actuator with piezoelectric material, in which the electric field and the deflection in the embodiment depicted in FIG. 8A are developed parallel to the optically effective surface 32.

FIG. 8B schematically shows the schematic structure of a bimorph actuator 46 which comprises a first actuator layer 47 and a second actuator layer 48. The two actuator layers 47, 48 can be deflected in opposite directions (depicted by arrows in FIG. 8B), and so one actuator layer 47 expands and the other actuator layer 48 contracts, whereby a deformation in the actuator 46 is brought about.

FIG. 8C shows an optical element designed as a mirror Mx, 117 having a bimorph actuator 46 as explained in FIG. 8B. It is connected by way of an adhesive connection to the back side 33 of the main body 31 which is deformed in the event of bimorph actuator deflection. The functionality is similar to that of an actuator arranged in surface-normal fashion which uses the deformation arising from the secondary effect of a change in geometry perpendicular to the main deflection. However, it differs therefrom in that the main contribution of the deformation is brought about by the deformation of the bimorph actuator 46 itself, as explained in FIG. 8B, and not by way of a contraction of the material in the main body 31 due to a change in geometry of the actuator.

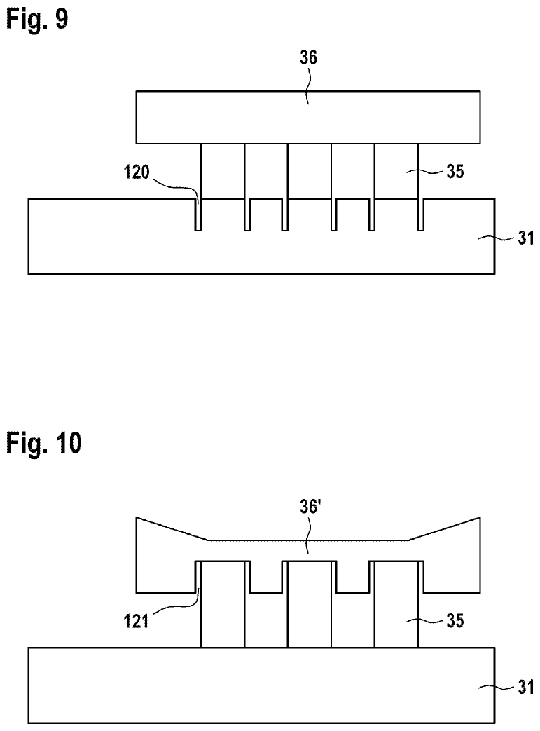

FIG. 9 shows an advantageous variant of the disclosure, in which use is made of a decoupling element 120. In this case, a main body 31 is connected to a free back plate 36 by way of actuators 35 in the manner already described. In the example shown, mechanical decoupling in the region of the connection of the actuators 35 to the main body 31 is achieved by the decoupling elements embodied as clear cuts 120 in the main body 31. For example, should the actuators 35 be embodied as cylindrical solid-state actuators, the decoupling elements 120 can be realized as all-round annular grooves. In the example shown, the decoupling elements 120 are formed in the main body 31 only. It is self-evident that a corresponding measure is also conceivable for the back plate 36.

FIG. 10 shows an embodiment of the disclosure in which a back plate 36′ is designed such that its thickness varies laterally. Furthermore, the back plate 36′ exhibits cutouts 121, in which the actuators 35 are arranged in part. What is achieved by the laterally varying thickness of the back plate 36′ is that the stiffness of the back plate 31′ is comparable to the stiffness in the inner regions, even in its edge regions. Furthermore, a certain amount of installation space can be saved by arranging the actuators 35 in the cutouts 121. In this context, the measures shown in FIG. 10 need not necessarily be used in combination; naturally, it is also conceivable in each case to use only a back plate with a laterally varying thickness or else a back plate with cutouts.

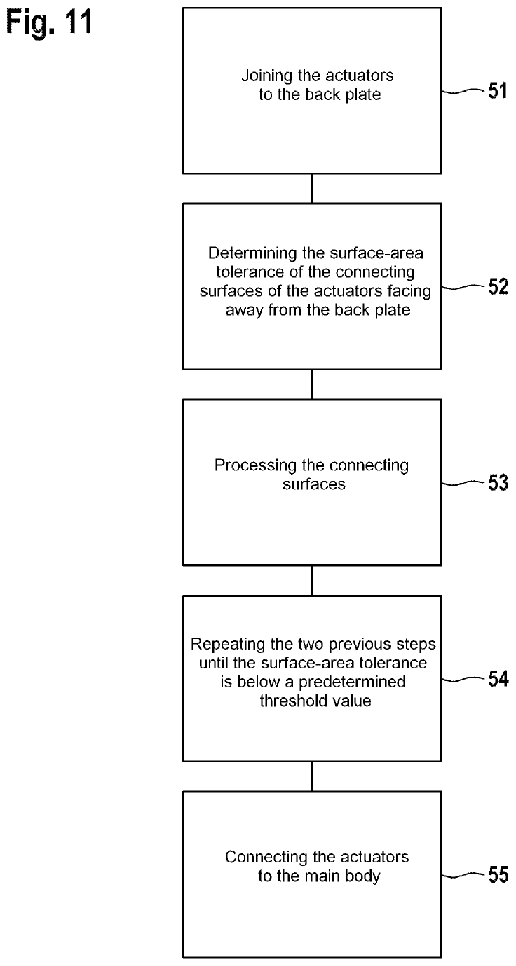

FIG. 11 describes a possible method for producing an optical assembly according to the disclosure.

The actuators are connected to the back plate in a first method step 51.

The surface-area tolerance of the connecting surfaces of the actuators facing away from the back plate is determined in a second method step 52.

The connecting surfaces are processed in a third method step 53.

The two previous steps are repeated in a fourth method step 54, until the surface-area tolerance is below a predetermined threshold value.

The actuators are connected to the main body in a fifth method step 55.

### LIST OF REFERENCE SIGNS

1 Projection exposure apparatus
2 Illumination system
3 Radiation source
4 Illumination optical unit
5 Object field
6 Object plane
7 Reticle
8 Reticle holder
9 Reticle displacement drive
10 Projection optical unit
11 Image field
12 Image plane
13 Wafer
14 Wafer holder
15 Wafer displacement drive
16 EUV radiation
17 Collector
18 Intermediate focal plane
19 Deflection mirror
20 Facet mirror
21 Facets
22 Facet mirror
23 Facets
30 Optical assembly
31 Main body
32 Optically effective surface
33 Back side of the main body
34 Bearing of the main body
35 Actuator
36, 36′ Back plate
37.1-37.3 Split back plate
38 Spherical joining surface
39 Back plate
40.1-40.4 Split back plate
41 Shearing actuator
42 Shearing actuator
43 End face
44 Normal actuator
45 Longitudinal side
46 Bimorph actuator
47 Actuator layer 1
48 Actuator layer 2
49 Strain sensor
51 Method step 1
52 Method step 2
53 Method step 3
54 Method step 4
55 Method step 5
101 Projection exposure apparatus
102 Illumination system
107 Reticle
108 Reticle holder
110 Projection optical unit
113 Wafer
114 Wafer holder
116 DUV radiation
117 Optical element
118 Mounts
119 Lens housing
M1-M6 Mirrors
120 Annular groove
121 Cutout

What is claimed is:

1. An optical assembly, comprising:
an optical element comprising a main body;
at least two actuators configured to deform the main body; and
a back plate comprising a sensor,
wherein:
the at least two actuators are connected to a connecting surface of a back side of the main body;
the at least two actuators are connected to a connecting surface of the back plate;
the back plate is mounted exclusively by way of the actuators; and
the back plate has a thickness that varies over a lateral extent of the back plate.

2. The optical assembly of claim 1, further comprising a decoupling element configured to laterally decouple, wherein the decoupling element is between the at least two actuators and the main body, and/or the decoupling element is between the at least two actuators and the back plate.

3. The optical assembly of claim 1, wherein the back side of the main body comprises a flat portion.

4. The optical assembly of claim 1, wherein the main body has a thickness that varies over a lateral extent of the main body.

5. The optical assembly of claim 1, wherein the at least two actuators are at least partially disposed in cutouts in the back plate and/or the main body.

6. The optical assembly of claim 1, wherein the back side of the main body has a plurality of flat portions that do not extend parallel to one another.

7. The optical assembly of claim 6, comprising a plurality of flat back plates, each flat back plate being aligned parallel with a flat portion of the back side of the main body.

8. The optical assembly of claim 1, wherein an effective direction of at least one of the at least two actuators is normal to the connecting surface of the actuator.

9. The optical assembly of claim 1, wherein an effective direction of at least one of the at least two actuators is normal to an optically effective surface of the optical element.

10. The optical assembly of claim 1, wherein at least two actuators have different properties.

11. The optical assembly of claim 1, wherein the optical element comprises a mirror.

12. The optical assembly of claim 1, wherein the optical element comprises a concave mirror wherein the mirror with a radius of curvature of from 180 millimeters to 260 millimeters.

13. The optical assembly of claim 1, wherein the back plate has a lower stiffness than the main body.

14. The optical assembly of claim 1, wherein the sensor comprises a strain sensor or temperature sensor.

15. A an apparatus, comprising:
an optical assembly according to claim 1,
wherein the apparatus is a semiconductor lithography projection exposure apparatus.

16. An optical assembly, comprising:
an optical element comprising a main body;
at least two actuators; and
a back plate,
wherein:
the at least two actuators are configured to deform the main body;
the at least two actuators are connected to a connecting surface of a back side of the main body;
the at least two actuators are connected to a connecting surface of the back plate;
the back plate is mounted exclusively by way of the actuators;
the back side of the main body has a plurality of flat portions that do not extend parallel to one another;
the optical assembly comprises a plurality of flat back plates; and
each flat back plate is parallel with a flat portion of the back side of the main body.

17. The optical assembly of claim 16, further comprising a decoupling element configured to laterally decouple, wherein the decoupling element is between the at least two actuators and the main body, and/or the decoupling element is between the at least two actuators and the back plate.

18. The optical assembly of claim 16, wherein the main body has a thickness that varies over a lateral extent of the main body.

19. The optical assembly of claim 16, wherein the at least two actuators are at least partially disposed in cutouts in at least one back plate and/or the main body.

20. The optical assembly of claim 16, wherein the surface of at least one back plate facing the main body and the surface of at least one back plate facing away from the main body extends at a constant distance from the back side of the main body.

21. The optical assembly of claim 16, wherein an effective direction of at least one of the at least two actuators is normal to the connecting surface of the main body.

22. The optical assembly of claim 16, wherein an effective direction of at least one of the at least two actuators is normal to an optically effective surface of the optical element.

23. The optical assembly of claim 16, wherein the at least two actuators have different properties.

24. The optical assembly of claim 16, wherein the optical element comprises a mirror.

25. The optical assembly of claim 16, wherein the optical element comprises a concave mirror wherein the mirror having a radius of curvature of from 180 millimeters to 260 millimeters.

26. The optical assembly of claim 16, wherein at least one of the back plates has a lower stiffness than the main body.

27. The optical assembly of claim 16, wherein the back plate comprises a sensor.

28. The optical assembly of claim 27, wherein the sensor comprises a strain sensor or a temperature sensor.

29. An apparatus, comprising:
an optical assembly according to claim 16,
wherein the apparatus is a semiconductor lithography projection exposure apparatus.

30. A method of making an optical assembly comprising an optical element, an actuator configured to deform the optical element, and a back plate, the optical element comprising a main body and an optically effective surface, the actuator being between the main body and the back plate, the method comprising:
a) connecting the actuator to the back plate;
b) determining a surface-area tolerance of the connecting surface facing away from the back plate;
c) processing the connecting surfaces;
repeating b) and c) until the surface-area tolerance is below a predetermined threshold value; and
connecting the actuator to the main body.

31. The method of claim 30, wherein the optically effective surface is processed after assembling the actuator.

32. The method of claim 30, wherein a plurality of actuators are arranged on the back plate.
